(19) United States
(12) Patent Application Publication
(10) Pub. No.: US 2020/0219833 A1
(43) Pub. Date: Jul. 9, 2020

(54) SEMICONDUCTOR PACKAGE

(71) Applicant: SAMSUNG ELECTRONICS CO., LTD., Suwon-si (KR)

(72) Inventors: Youngkwan LEE, Suwon-si (KR); Youngsik HUR, Suwon-si (KR); Junghyun Cho, Suwon-si (KR); Taehee Han, Suwon-si (KR); Jongrok Kim, Suwon-si (KR)

(73) Assignee: SAMSUNG ELECTRONICS CO., LTD., Suwon-si (KR)

(21) Appl. No.: 16/704,217

(22) Filed: Dec. 5, 2019

(30) Foreign Application Priority Data
Jan. 8, 2019 (KR) 10-2019-0002421

(51) Int. Cl. H01L 23/00; H01L 23/31; H01L 23/498

(52) U.S. Cl. CPC H01L 24/05; H01L 24/13; H01L 24/45; H01L 2224/05147; H01L 23/3121; H01L 23/49816; H01L 2224/02372; H01L 24/73

(57) ABSTRACT

A semiconductor package may include: a connection structure including an insulating member having a first surface having a recess portion and a second surface opposing the first surface, a plurality of first pads disposed on a bottom surface of the recess portion, a plurality of second pads embedded in the second surface of the insulating member, and a redistribution layer disposed between the plurality of first pads and the plurality of second pads and connected to the plurality of first and second pads; a semiconductor chip disposed on the first surface of the insulating member and having a plurality of connection electrodes electrically connected, respectively, to the plurality of first pads; and a passivation layer disposed on the second surface of the insulating member and having a plurality of openings exposing, respectively, the plurality of second pads.

### CROSS-REFERENCE TO RELATED APPLICATION(S)

This application claims benefit of priority to Korean Patent Application No. 10-2019-0002421 filed on Jan. 8, 2019 in the Korean Intellectual Property Office, the disclosure of which is incorporated herein by reference in its entirety.

### BACKGROUND

### 1. Field

The present disclosure relates to a semiconductor package.

### 2. Description of Related Art

In accordance with improvement of specifications of a set and/or use of a high bandwidth memory (HBM), an die-to-die interposer market has grown Currently, silicon has been mainly used as a material of the interposer, but development of a glass or organic manner has been conducted in order to increase an area and reduce a cost.

Meanwhile, a semiconductor package has been required to have a small size and a high reliability. However, when a thickness of a semiconductor chip or a thickness of an encapsulant is reduced, there is a risk that an assembly yield problem will occur and characteristics of the semiconductor package will be deteriorated. Therefore, the semiconductor package has been required to have a small size through a reduction in a thickness of a connection structure corresponding to a substrate portion.

### SUMMARY

An aspect of the present disclosure may provide a semiconductor package capable of having a small size and a high reliability (for example, reliability on a board level).

According to an aspect of the present disclosure, a semiconductor package may include: a connection structure including an insulating member comprising a first surface having a recess portion and a second surface opposing the first surface, a plurality of first pads disposed on a bottom surface of the recess portion, a plurality of second pads embedded in the second surface of the insulating member, and a redistribution layer disposed between the plurality of first pads and the plurality of second pads and connected to the plurality of first and second pads; a semiconductor chip disposed on the first surface of the insulating member and having a plurality of connection electrodes electrically connected, respectively, to the plurality of first pads; and a passivation layer disposed on the second surface of the insulating member and having a plurality of openings exposing, respectively, the plurality of second pads.

According to another aspect of the present disclosure, a semiconductor package may include: a connection structure including an insulating member having a first surface having a recess portion and a second surface opposing the first surface, a plurality of bonding pads disposed on a bottom surface of the recess portion, and a redistribution layer disposed on the insulating member and connected to the plurality of bonding pads; at least one semiconductor chip disposed on the first surface of the insulating member and having a plurality of connection electrodes connected, respectively, to the plurality of bonding pads by wires; an encapsulant disposed on the first surface of the insulating member and encapsulating the at least one semiconductor chip; a plurality of underbump metallurgy (UBM) pads electrically connected to the redistribution layer and embedded in the second surface of the insulating member; and a passivation layer disposed on the second surface of the insulating member, having a plurality of openings exposing, respectively, the plurality of UBM pads, and including an insulating material different from that of the insulating member.

### BRIEF DESCRIPTION OF DRAWINGS

The above and other aspects, features, and advantages of the present disclosure will be more clearly understood from the following detailed description taken in conjunction with the accompanying drawings, in which:

FIG. 1 is a schematic block diagram illustrating an example of an electronic device system;

FIG. 2 is a schematic perspective view illustrating an example of an electronic device;

FIG. 3 is a schematic cross-sectional view illustrating a case in which a three-dimensional (3D) ball grid array (BGA) package is mounted on a main board of an electronic device;

FIG. 4 is a schematic cross-sectional view illustrating a case in which a 2.5D silicon interposer package is mounted on a main board;

FIG. 5 is a schematic cross-sectional view illustrating a case in which a 2.5D organic interposer package is mounted on a main board;

FIG. 6 is a schematic cross-sectional view illustrating a semiconductor package according to an exemplary embodiment in the present disclosure;

FIG. 7 is a schematic plan view illustrating the semiconductor package of FIG. 6;

FIG. 8 is an enlarged cross-sectional view of portion “A” of the semiconductor package of FIG. 6;

FIGS. 9A through 9F are cross-sectional views for describing main processes of manufacturing a connection structure in a method of manufacturing the semiconductor package illustrated in FIG. 6; and

FIGS. 10A through 10C are cross-sectional views for describing main processes of mounting a semiconductor chip in the method of manufacturing the semiconductor package illustrated in FIG. 6.

### DETAILED DESCRIPTION

Hereinafter, exemplary embodiments in the present disclosure will be described with reference to the accompanying drawings. In the accompanying drawings, shapes, sizes, and the like, of components may be exaggerated or shortened for clarity.

The term “an exemplary embodiment” used herein does not refer to the same exemplary embodiment, and is provided to emphasize a particular feature or characteristic different from that of another exemplary embodiment. However, exemplary embodiments provided herein are considered to be able to be implemented by being combined in whole or in part one with one another. For example, one element described in a particular exemplary embodiment, even if it is not described in another exemplary embodiment, may be understood as a description related to another exemplary embodiment, unless an opposite or contradictory description is provided therein.

Terms used herein are used only in order to describe an exemplary embodiment rather than limiting the present disclosure. In this case, singular forms include plural forms unless interpreted otherwise in context.

Electronic Device

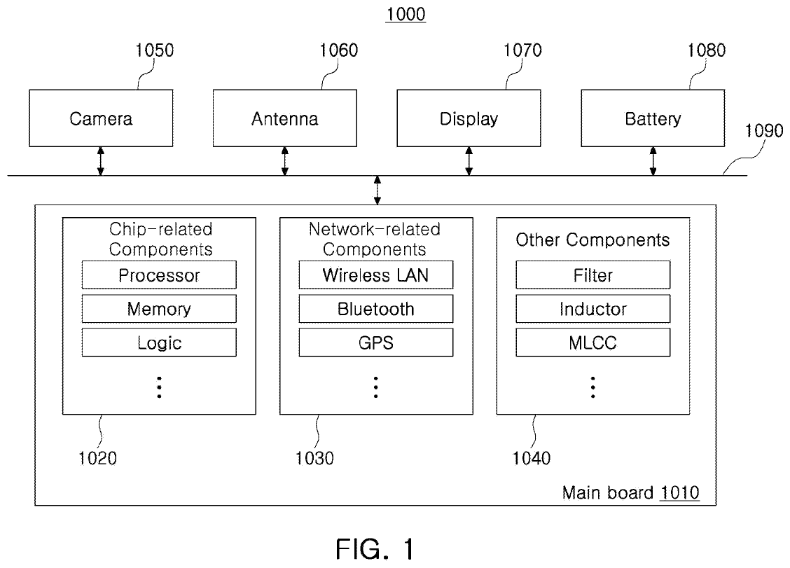

FIG. 1 is a schematic block diagram illustrating an example of an electronic device system.

Referring to FIG. 1, an electronic device 1000 may accommodate a mainboard 1010 therein. The mainboard 1010 may include chip related components 1020, network related components 1030, other components 1040, and the like, physically or electrically connected thereto. These components may be connected to others to be described below to form various signal lines 1090.

The chip related components 1020 may include a memory chip such as a volatile memory (for example, a dynamic random access memory (DRAM)), a non-volatile memory (for example, a read only memory (ROM)), a flash memory, or the like; an application processor chip such as a central processor (for example, a central processing unit (CPU)), a graphics processor (for example, a graphics processing unit (GPU)), a digital signal processor, a cryptographic processor, a microprocessor, a microcontroller, or the like; and a logic chip such as an analog-to-digital (ADC) converter, an application-specific integrated circuit (ASIC), or the like. However, the chip related components 1020 are not limited thereto, but may also include other types of chip related components. In addition, the chip related components 1020 may be combined with each other.

The network related components 1030 may include protocols such as wireless fidelity (Wi-Fi) (Institute of Electrical And Electronics Engineers (IEEE) 802.11 family, or the like), worldwide interoperability for microwave access (WiMAX) (IEEE 802.16 family, or the like), IEEE 802.20, long term evolution (LTE), evolution data only (Ev-DO), high speed packet access+(HSPA+), high speed downlink packet access+(HSDPA+), high speed uplink packet access+(HSUPA+), enhanced data GSM environment (EDGE), global system for mobile communications (GSM), global positioning system (GPS), general packet radio service (GPRS), code division multiple access (CDMA), time division multiple access (TDMA), digital enhanced cordless telecommunications (DECT), Bluetooth, 3G, 4G, and 5G protocols, and any other wireless and wired protocols, designated after the abovementioned protocols. However, the network related components 1030 are not limited thereto, but may also include a variety of other wireless or wired standards or protocols. In addition, the network related components 1030 may be combined with each other, together with the chip related components 1020 described above.

Other components 1040 may include a high frequency inductor, a ferrite inductor, a power inductor, ferrite beads, a low temperature co-fired ceramic (LTCC), an electromagnetic interference (EMI) filter, a multilayer ceramic capacitor (MLCC), or the like. However, other components 1040 are not limited thereto, but may also include passive components used for various other purposes, or the like. In addition, other components 1040 may be combined with each other, together with the chip related components 1020 or the network related components 1030 described above.

Depending on a type of the electronic device 1000, the electronic device 1000 may include other components that may or may not be physically or electrically connected to the mainboard 1010. These other components may include, for example, a camera 1050, an antenna 1060, a display 1070, a battery 1080, an audio codec (not illustrated), a video codec (not illustrated), a power amplifier (not illustrated), a compass (not illustrated), an accelerometer (not illustrated), a gyroscope (not illustrated), a speaker (not illustrated), a mass storage unit (for example, a hard disk drive) (not illustrated), a compact disk (CD) drive (not illustrated), a digital versatile disk (DVD) drive (not illustrated), or the like. However, these other components are not limited thereto, but may also include other components used for various purposes depending on a type of electronic device 1000, or the like.

The electronic device 1000 may be a smartphone, a personal digital assistant (PDA), a digital video camera, a digital still camera, a network system, a computer, a monitor, a tablet PC, a laptop PC, a netbook PC, a television, a video game machine, a smartwatch, an automotive component, or the like. However, the electronic device 1000 is not limited thereto, but may be any other electronic device processing data.

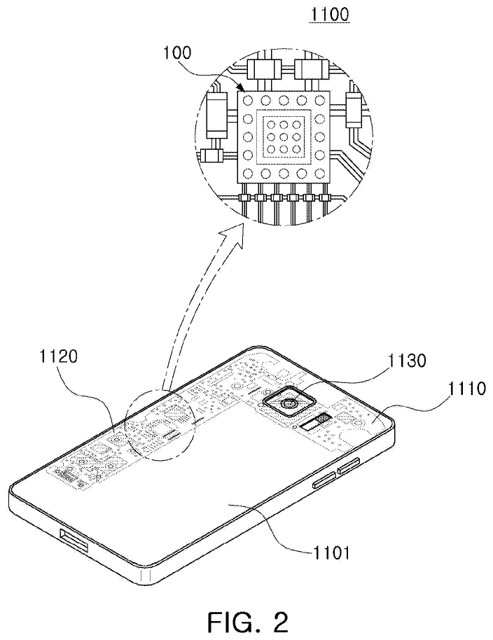

FIG. 2 is a schematic perspective view illustrating an example of an electronic device.

Referring to FIG. 2, a semiconductor device may be used for various purposes in the various electronic devices 1000 as described above. For example, a motherboard 1110 may be accommodated in a body 1101 of a smartphone 1100, and various electronic components 1120 may be physically or electrically connected to the motherboard 1110. In addition, other components that may or may not be physically or electrically connected to the motherboard 1110, such as a camera module 1130, may be accommodated in the body 1101. Some of the electronic components 1120 may be chip related components, and some of the chip related components may be a semiconductor device 1121. Meanwhile, the electronic device is not necessarily limited to the smartphone 1100, but may be other electronic devices.

Semiconductor Device (or Semiconductor Package)

Generally, numerous fine electrical circuits are integrated in a semiconductor chip. However, the semiconductor chip may not serve as a semiconductor finished product in oneself, and may be damaged due to external physical or chemical impact. Therefore, the semiconductor chip is not used in oneself, and is packaged and is used in an electronic device, or the like, in a package state.

The reason why semiconductor packaging is required is that there is a difference in a circuit width between the semiconductor chip and a mainboard of the electronic device in terms of electrical connection. In detail, a size of connection pads of the semiconductor chip and an interval between the connection pads of the semiconductor chip are very fine, but a size of component mounting pads of the mainboard used in the electronic device and an interval between the component mounting pads of the mainboard are significantly larger than those of the semiconductor chip. Therefore, it may be difficult to directly mount the semiconductor chip on the mainboard, and packaging technology for buffering a difference in a circuit width between the semiconductor and the mainboard is required.

A semiconductor device manufactured by the packaging technology described above will hereinafter be described in more detail with reference to the drawings.

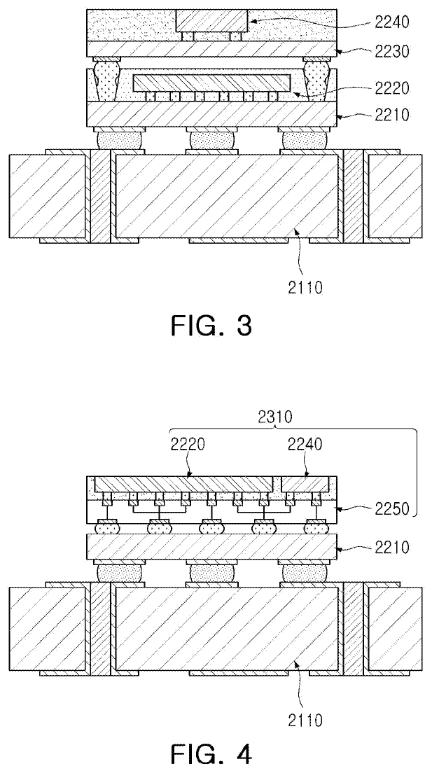

FIG. 3 is a schematic cross-sectional view illustrating a case in which a three-dimensional (3D) ball grid array (BGA) package is mounted on a main board of an electronic device.

An application specific integrated circuit (ASIC) such as a graphics processing unit (GPU) among semiconductor chips is very expensive, and it is thus very important to perform packaging on the ASIC at a high yield. For this purpose, a ball grid array (BGA) substrate 2210, or the like, that may redistribute several thousands to several hundreds of thousands of connection pads is prepared before a semiconductor chip is mounted, and the semiconductor chip that is expensive, such as a GPU 2220, or the like, is mounted and packaged on the BGA substrate 2210 by surface mounting technology (SMT), or the like, and is then mounted ultimately on a main board 2110.

Meanwhile, in a case of the GPU 2220, it is required to significantly reduce a signal path between the GPU 2220 and a memory such as a high bandwidth memory (HBM). To this end, a product in which a semiconductor chip such as the HBM 2240 is mounted and then packaged on an interposer 2230, and is then stacked on a package in which the GPU 2220 is mounted, in a package-on-package (POP) form is used. However, in this case, a thickness of a device is excessive increased, and there is a limitation in significantly reducing the signal path.

FIG. 4 is a schematic cross-sectional view illustrating a case in which a 2.5D silicon interposer package is mounted on a main board.

As a method for solving the problem described above, it may be considered to manufacture a semiconductor device 2310 by 2.5D interposer technology of surface-mounting and then packaging a first semiconductor chip such as a GPU 2220 and a second semiconductor chip such as an HBM 2240 side-by-side with each other on a silicon interposer 2250. In this case, the GPU 2220 and the HBM 2240 having several thousands to several hundreds of thousands of connection pads may be redistributed by the silicon interposer 2250, and may be electrically connected to each other at the shortest path. In addition, when the semiconductor device 2310 is again mounted and redistributed on a BGA substrate 2210, or the like, the semiconductor device 2310 may be ultimately mounted on a main board 2110. However, it is very difficult to form through-silicon vias (TSVs) in the silicon interposer 2250, and a cost required for manufacturing the silicon interposer 2250 is significantly high, and the silicon interposer 2250 is thus disadvantageous in increasing an area and reducing a cost.

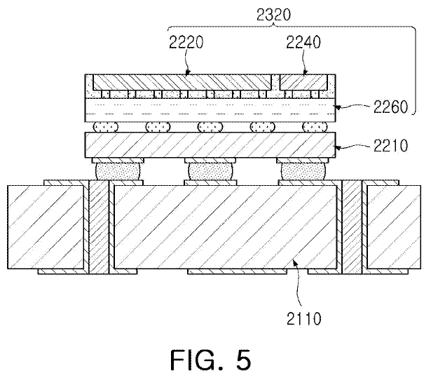

FIG. 5 is a schematic cross-sectional view illustrating a case in which a 2.5D organic interposer package is mounted on a main board.

As a method for solving the problem described above, it may be considered to use an organic interposer 2260 instead of the silicon interposer 2250. For example, it may be considered to manufacture a semiconductor device 2320 by 2.5D interposer technology of surface-mounting and then packaging a first semiconductor chip such as a GPU 2220 and a second semiconductor chip such as an HBM 2240 side-by-side with each other on the organic interposer 2260. In this case, the GPU 2220 and the HBM 2240 having several thousands to several hundreds of thousands of connection pads may be redistributed by the organic interposer 2260, and may be electrically connected to each other at the shortest path. In addition, when the semiconductor device 2320 is again mounted and redistributed on a BGA substrate 2210, or the like, the semiconductor device 2320 may be ultimately mounted on a main board 2110. In addition, the organic interposer may be advantageous in increasing an area and reducing a cost.

Meanwhile, such a semiconductor device 2320 is manufactured by performing a package process of mounting chips 2220 and 2240 on the organic interposer 2260 and then molding the chips. The reason is that when a molding process is not performed, the semiconductor device is not handled, such that the semiconductor device may not be connected to the BGA substrate 2210, or the like. Therefore, rigidity of the semiconductor device is maintained by the molding. However, when the molding process is performed, warpage of the semiconductor device may occur, fillability of an underfill resin may be deteriorated, and a crack between a die and a molding material of the chips 2220 and 2240 may occur, due to mismatch between coefficients of thermal expansion (CTEs) of the interposer 2260 and the molding material of the chips 2220 and 2240, as described above.

Various exemplary embodiments in the present disclosure will hereinafter be described in detail with reference to the accompanying drawings.

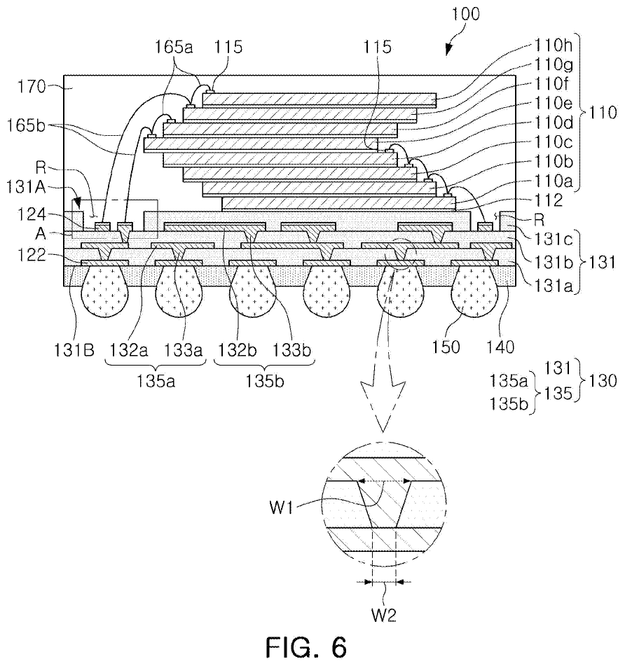

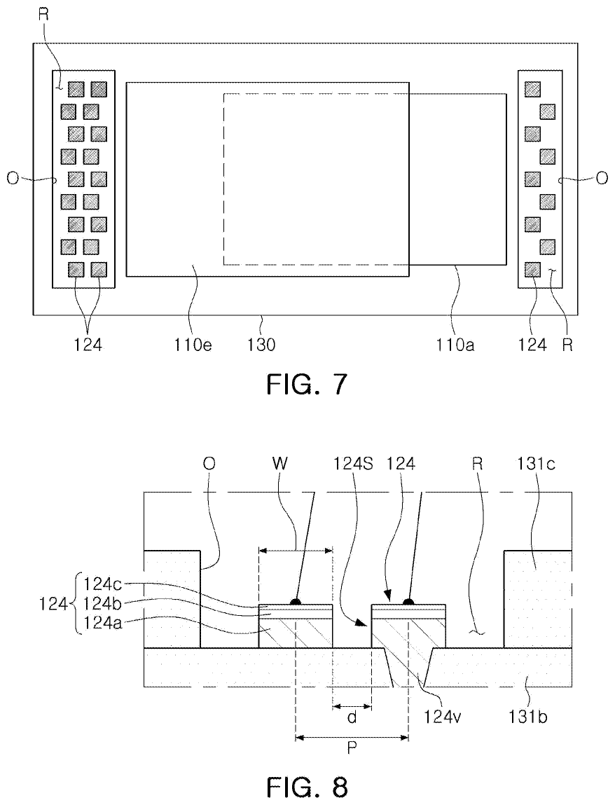

FIG. 6 is a schematic cross-sectional view illustrating a semiconductor package according to an exemplary embodiment in the present disclosure, and FIG. 7 is a schematic plan view illustrating (illustrating some 110a and 110e of semiconductor chips) the semiconductor package of FIG. 6.

Referring to FIGS. 6 and 7, a semiconductor package 100 according to the present exemplary embodiment may include a connection structure 130 having a plurality of first and second pads 124 and 122 and a redistribution layer 135 disposed between the plurality of first and second pads 124 and 122, a semiconductor chip 110 disposed on the connection structure 130 and electrically connected to the plurality of first pads 124, and an encapsulant 170 disposed on the connection structure 130 and encapsulating the semiconductor chip 110.

The connection structure 130 used in the present exemplary embodiment may be used as a packaging substrate in order to mount the semiconductor chip 110 on a mainboard. The connection structure 130 may include an insulating member 131 having first and second surfaces 131A and 131B opposing each other, and recess portions R may be formed in the first surface 131A of the insulating member 131. The plurality of first pads 124 may be disposed on bottom surfaces of the recess portions R. Therefore, a thickness of the connection structure 130 according to the present exemplary embodiment may be reduced as compared to a form in which the plurality of first pads 124 are disposed on the first surface of the insulating member 131.

In the present exemplary embodiment, the insulating member 131 may include first to third insulating layers 131a, 131b, and 131c, and the redistribution layer 135 may include a first redistribution layer 135a (also referred to as a “lower redistribution layer”) disposed on the first insulating layer 131a and a second redistribution layer 135b (also referred to as an “upper redistribution layer”) disposed on the second insulating layer 131b. In the present exemplary embodiment, a redistribution layer having a two-level structure is exemplified, but the redistribution layer may be implemented in a one-level or three-level or more structure.

The first redistribution layer 135a may include a first redistribution pattern 132a disposed on the first insulating layer 131a and first redistribution vias 133a connected to the plurality of second pads 122 through the first insulating layer 131a. The plurality of second pads 122 may be embedded in the second surface 131B of the insulating member 131. As illustrated in FIG. 6, the plurality of second pads 122 may be substantially coplanar with the second surface 131B of the insulating member 131. In the present specification, the first and second pads 124 and 122 may also be referred to as “bonding pads” and “underbump metallurgy (UBM) pads”, respectively.

The second redistribution layer 135b may include a second redistribution pattern 132b disposed on the second insulating layer 131b and second redistribution vias 133b connected to the first redistribution pattern 132a through the second insulating layer 131b, similar to the first redistribution layer 135a.

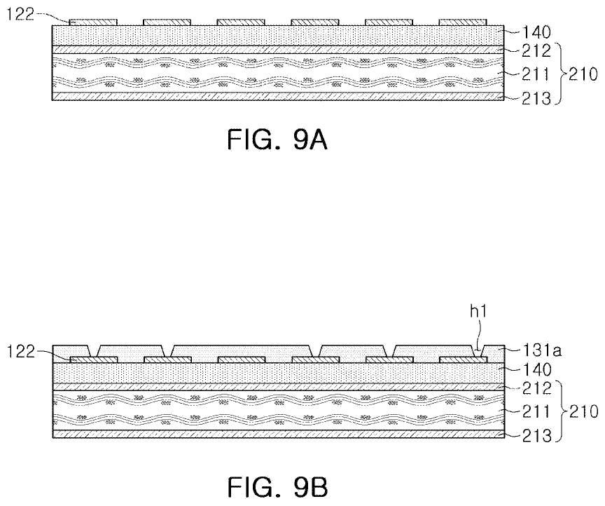

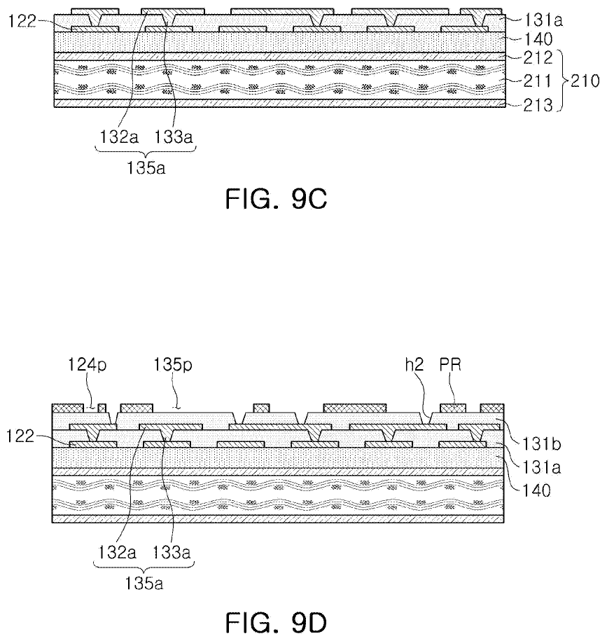

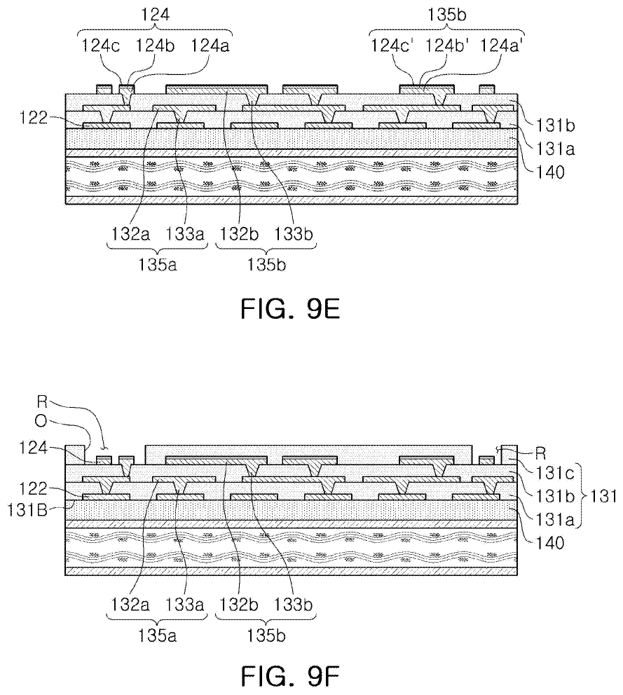

In the present exemplary embodiment, the plurality of first pads 124 may be disposed on the same level as that of the second redistribution layer 135b, that is, on the second insulating layer 131b. The second redistribution layer 135b may be configured to be electrically connected to the plurality of first pads 124, in addition to the first redistribution layer 135a. The second redistribution layer 135b may be formed by the same process as a process of forming the plurality of first pads 124 (see FIGS. 9D and 9E).

In the present exemplary embodiment, the first and second redistribution patterns 132a and 132b may have integrated structures with the first and second redistribution vias 133a and 133b, respectively. Similarly, when the first pad 124 has a via 124v, the first pad 124 may have an integrated structure with the via 124v.

In the present specification, a term “integrated structure” does not mean that two components are simply in contact with each other, and refers to a structure in which two components are formed integrally with (or continuously to) each other using the same material by the same process. For example, when a pattern (a redistribution pattern or a pad) and a via are formed together by the same plating process, the pattern and the via may be called the integrated structure. On the other hand, in the present exemplary embodiment, even though the second pad 122 embedded in the first insulating layer 131a and the first redistribution layer 135a (particularly, the first redistribution via 133a) are in contact with each other, the second pad 122 and the first redistribution layer 135a may be discontinuous structures formed by different processes (see FIGS. 9B through 9E).

In the present exemplary embodiment, as illustrated in FIG. 6, each of the first and second redistribution vias 133a and 133b may have a cross-sectional shape in which a width “W1” thereof adjacent to the first surface 131A is greater than a width “W2” thereof adjacent to the second surface 131B.

The semiconductor chip 110 used in the present exemplary embodiment may include a plurality of semiconductor chips 110a, 110b, 110c, 110d, 110e, 110f, 110g, and 110h stacked on the connection structure. The plurality of semiconductor chips 110a to 110h may be bonded to each other using adhesive members 112. The plurality of semiconductor chips 110a to 110h may include integrated circuits. For example, the integrated circuit may include a memory circuit or a logic circuit. The semiconductor chip 110 may include a connection electrode 115 connected to the integrated circuit and disposed on an upper surface (that is, an active surface) thereof.

The plurality of semiconductor chips 110a to 110h may be homogeneous products or heterogeneous products. For example, all of the plurality of semiconductor chips 110a to 110h may be memory chips. The memory chip may include various types of memory circuits such as a DRAM or a static random access memory (SRAM) a flash memory, a phase-change random access memory (PRAM), a resistive random access memory (ReRAM), a ferroelectric random access memory (FeRAM), or a magnetoresistive random access memory (MRAM). In this case, the plurality of semiconductor chips 110a to 110h may have the same size or different sizes depending on a type of memory circuits. A case in which the number of semiconductor chips 110a to 110h is eight is exemplified, for example, in FIG. 6, but the number of semiconductor chips 110a to 110h is not limited thereto, and may be one or another number. In a specific example, the semiconductor chip may include a high bandwidth memory (HBM) chip.

The plurality of semiconductor chips 110a to 110h may be disposed to be sequentially offset so as to expose the connection electrodes 115. For example, the plurality of semiconductor chips 110a to 110h may be stacked to be sequentially offset toward one edge of the connection structure 130. As illustrated in FIG. 6, some semiconductor chips 110a, 110b, 110c, and 110d may be sequentially offset toward one edge of the connection structure 130, and the other semiconductor chips 110e, 110f, 110g, and 110h may be sequentially offset toward the other edge of the connection structure 130 disposed at an opposite direction.

The plurality of semiconductor chips 110a to 110h may be connected to each other through first wires 165a, and may be connected, respectively, to the first pads124 disposed in the connection structure 130 through second wires 165b.

The plurality of first pads 124 may be disposed on bottom surfaces of two recess portions R disposed at opposite edges of the connection structure 130 as illustrated in FIG. 7, that is, on the second insulating layer 131b exposed through openings “O” of the third insulating layer 131c. In order to miniaturize the connection structure 130, the first pads 124 used as the bonding pads in the present exemplary embodiment may be implemented in a fine pitch. In the present exemplary embodiment, a method of implementing the first pads 124 in a finer pitch by changing a structure of the first pads 124 (or a process of forming the first pads 124) may be provided.

As illustrated in FIG. 8, each of the plurality of first pads 124 may include a metal pad 124a and metal layers 124b and 124c disposed on an upper surface of the metal pad 124a. In this case, the metal layers 124b and 124c may be formed on only the upper surface of the metal pad 124a so that side surfaces 124S of the metal pad 124a are exposed.

As described above, a distance between the first pads 124 may be set to a distance “d” between the metal pads 124a by preventing the metal layers 124b and 124c from being formed on the side surfaces of the metal pads 124a in a process (see FIGS. 9D and 9E) of forming the first pads 124. Therefore, the distance between the metal pads 124a need not to be sufficiently secured in advance in consideration of thicknesses of the metal layers 124b and 124c that are to be formed on the side surfaces of the metal pads 124a, and a pitch “P” of the first pad 124 may thus be significantly reduced. For example, the pitch “P” of the plurality of first pads may be 65 μm or less, furthermore, 60 μm or less. The pitch “P” of the plurality of the first pads 124 may be between 55 μm and 60 μm. Meanwhile, the metal layers 124b and 124c may include two different metal layers. For example, the metal pad 124a may include a copper (Cu) pad, and the metal layers 124b and 124c may include nickel/gold (Ni/Au) layers. The Ni/Au layers may be Ni/Au plating layers.

The second pads 122 may be provided as underbump metallurgy (UBM) pads.

The semiconductor package 100 according to the present exemplary embodiment may further include a passivation layer 140 disposed on a lower surface of the connection structure 130 and having a plurality of an opening at least portions of the plurality of the second pads 122. The passivation layer 140 may protect the connection structure 130 from external physical or chemical damage. In addition, the semiconductor package 100 may further include a plurality of electrical connection metals 150 disposed on the passivation layer 140 and connected, respectively, to the plurality of second pads 122.

The respective components included in the semiconductor package 100 according to the present exemplary embodiment will hereinafter be described in more detail.

The connection structure 130 may redistribute the respective connection electrodes 115 of the semiconductor chips 110. Several thousands to several hundreds of thousands of connection electrodes 115 of the semiconductor chips 110 having various functions may be redistributed by the connection structure 130, and may be physically or electrically externally connected through the electrical connection metals 150 depending on functions. The plurality of insulating layers 131a to 131c may serve as dielectric layers of the connection structure 130, and a material of each of the plurality of insulating layers 131a to 131c may be an organic insulating material such as a thermosetting resin such as an epoxy resin, a thermoplastic resin such as a polyimide resin, a resin in which the thermosetting resin or the thermoplastic resin is mixed with an inorganic filler. In the present exemplary embodiment, each of the insulating layers 131a to 131c may be formed of a photosensitive insulating material such as a photoimagable dielectric (PID) resin. Since each of the insulating layers 131a to 131c is formed of the photosensitive insulating material and a photolithography process is used, the redistribution layer 135 may be implemented in a fine pattern, and a thickness of the connection structure 130 may be reduced.

A material of the passivation layer 140 used in the present exemplary embodiment may be an insulating material. In this case, a thermosetting resin such as an epoxy resin, a thermoplastic resin such as a polyimide resin, a resin in which the thermosetting resin and the thermoplastic resin are mixed with an inorganic filler, for example, Ajinomoto Build-up Film (ABF), or the like, may be used as the insulating material. Particularly, when the passivation layer 140 is formed of the ABF unlike the insulating layers (for example, the PID) of the connection structure 130, reliability of a board level may be improved, and a desmear process for removing residues after laser drilling for forming openings in the passivation layer 140 may be effectively performed.

A plurality of redistribution layers 135 may redistribute the connection electrodes 115, and serve to connect the connection electrodes 115 to each other depending on a signal, power, or the like. Each of the redistribution layers 135 may include, for example, a conductive material such as copper (Cu), aluminum (Al), silver (Ag), tin (Sn), gold (Au), nickel (Ni), lead (Pb), titanium (Ti), or alloys thereof. The redistribution layers 135 may perform various functions depending on designs of corresponding layers. For example, the redistribution layers 135 may include ground (GND) patterns, power (PWR) patterns, signal (S) patterns, and the like. Here, the signal (S) patterns may include various signals except for the ground (GND) patterns, the power (PWR) patterns, and the like, such as data signals, and the like. In addition, the redistribution layers 135 may include via pads, electrical connection metal pads, and the like.

The plurality of second pads 122 may be UBM pads for improving connection reliability of the electrical connection metals 150. The second pads 122 may be formed in the openings of the passivation layer 140, and may be electrically connected to the redistribution layer 135 of the connection structure 130. For example, the second pads 122 may include a metal such as copper (Cu).

The electrical connection metals 150 may physically or electrically externally connect the semiconductor package 100. For example, the semiconductor package 100 may be mounted on a BGA substrate through the electrical connection metals 150. Each of the electrical connection metals 150 may be formed of a conductive material and a low melting point metal such as tin (Sn) or alloys including tin (Sn), more specifically, a solder, or the like.

Each of the electrical connection metals 150 may be a land, a ball, a pin, or the like. The electrical connection metals 150 may be formed as a multilayer or single layer structure. When the electrical connection metals 150 are formed as a multilayer structure, the electrical connection metals 150 may include a copper (Cu) pillar and a solder. When the electrical connection metals 150 are formed as a single layer structure, the electrical connection metals 150 may include a tin-silver solder or copper (Cu). However, this is only an example, and the electrical connection metals 150 are not limited thereto. The number, an interval, a disposition form, and the like, of electrical connection metals 150 are not particularly limited, but may be sufficiently modified depending on design particulars by those skilled in the art.

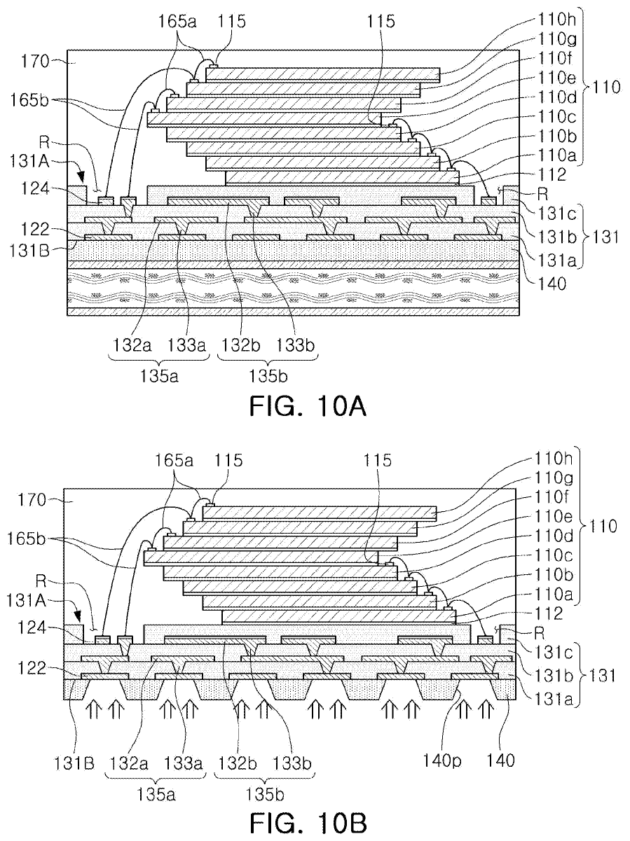

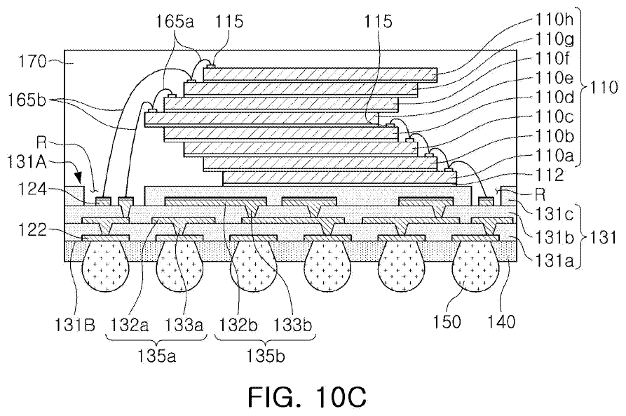

An example of a method of manufacturing a semiconductor package according to the present exemplary embodiment will hereinafter be described in detail. A method of manufacturing the semiconductor package 100 illustrated in FIG. 6 will be divided into and described as processes (FIGS. 9A through 9F) of forming the connection structure and processes (FIGS. 10A through 10C) of manufacturing the semiconductor package.

FIGS. 9A through 9F are cross-sectional views for describing main processes of forming the connection structure in a method of manufacturing the semiconductor package according to an exemplary embodiment in the present disclosure.

Referring to FIG. 9A, an insulating layer 140 and the second pads 122 may be formed on a carrier substrate 210.

The carrier substrate 210 may include a core layer 211 and metal layers 212 and 213 each formed on opposite surfaces of the core layer 211. The core layer 211 may be formed of an insulating resin or an insulating resin (for example, prepreg) including an inorganic filler and/or a glass fiber, and the metal layers 212 and 213 may be metal layers formed of copper (Cu). The carrier substrate 210 may include a release layer (not illustrated) formed on one surface thereof. Such a structure of the carrier substrate 210 and whether or not the release layer is used may be variously modified.

After the insulating layer 140 is formed, the second pads 122 may be formed on the insulating layer 140. The insulating layer 140 may be provided as the passivation layer in an ultimate structure. The insulating layer 140 may include, for example, ABF. The insulating layer 140 may be formed by laminating a film form or applying and hardening a liquid phase form. The second pads 122 may be formed of a pattern without having a via structure, and may be provided as UBM pads.

Then, referring to FIG. 9B, the first insulating layer 131a may be formed on the second pads 122, first via holes h1 may be formed in the first insulating layer 131a.

The first insulating layer 131a may be formed of a photosensitive insulating material such as a PID. After the first insulating layer 131a is formed, the first via holes h1 maybe formed by a photolithography process. As described above, the via holes h1 may be formed in a fine pitch using the first insulating layer 131a formed of the photosensitive insulating material and the photolithography process.

Then, referring to FIG. 9C, the first redistribution layer 135a connected to the second pads 122 may be formed.

The first redistribution layer 135a may be formed by forming a seed layer, forming a dry film having a desired pattern, and performing a plating process using the dry film. The dry film may be removed after the plating process, and a process of removing the seed layer disposed on an exposed upper surface of the first insulating layer 131a may be performed. The first redistribution layer 135a formed in the present process may include the first redistribution pattern 132a formed on the first insulating layer 131a and the first redistribution vias 133a connected to the second pads 122 through the via holes h1, and the first redistribution vias 133a may have a tapered cross-sectional shape by a formation direction thereof. For example, the first redistribution via 133a may have a greater width in an upper surface of the first insulating layer 131a than in a lower surface of the first insulating layer 131a.

Then, referring to FIG. 9D, the second insulating layer 131b having second via holes h2 may be formed, and a dry film PR for the first pads and the second redistribution layer may be formed on the second insulating layer 131b.

The second insulating layer 131b may be formed of a photosensitive insulating material that is the same as or similar to that of the first insulating layer 131a and may be formed by a process similar to that of FIG. 9B, and the second via holes h2 connected to the first redistribution layer 135a may be formed by a photolithography process. In addition, in a manner similar to that described in FIG. 9C, a seed layer (not illustrated) may be formed, the dry film PR may be formed on the seed layer, and openings 124p and 135p for the first pads and the second redistribution layer may be formed in the dry film PR. As described above, the second redistribution layer to be formed in a subsequent process may be formed to be electrically connected to the first pads and/or the first redistribution layer 135a while being disposed on the same level as that of the first pads on the second insulating layer 131b.

Then, referring to FIG. 9E, the plurality of first pads 124 and the second redistribution layer 135b may be formed on the second insulating layer 131b.

The plurality of first pads 124 and the second redistribution layer 135b may be performed by performing a plating process using the dry film PR formed in the previous process. Each of the plurality of first pads 124 may include the metal pad 124a and the metal layers 124b and 124c disposed on the upper surface of the metal pad 124a. The metal pad may include the Cu pad, and the metal layers may include the Ni/Au layers.

Since only the upper surface of the metal pad 124a is exposed, the metal layers 124b and 124c may be formed on only the exposed upper surface, as described above. As described above, the metal layers 124b and 124c are not formed on the side surfaces of the metal pad 124a, and the distance between the bonding pads 124 may thus be sufficiently secured. In the present exemplary embodiment, the second redistribution layer 135 may be formed together with the bonding pads 124, and may thus include a metal pattern 124′ and metal layers 124b′ and 124c′ that are the same as the metal layers 124b and 124c. The dry film may be removed after the plating process, and a process of removing the seed layer disposed on an exposed upper surface of the second insulating layer 131b may be performed.

Then, referring to FIG. 9F, the third insulating layer 131c having openings “O” opening regions in which the plurality of first pads 124 are arranged may be formed.

The plurality of first pads 124 may be disposed on the second insulating layer 131b exposed through the openings O of the third insulating layer 131c. As described above, the plurality of first pads 124 may be disposed on the bottom surfaces of the recess portions R of the insulating member 131, and a thickness of the connection structure 130 may thus be reduced by a thickness of the plurality of first pads 124. The plurality of first pads 124 may be arranged at a denser distance, and may thus be formed together with the second redistribution layer 135b on the same level as that of the second redistribution layer 135b without significantly increasing an area of the connection structure 130.

FIGS. 10A through 10C illustrate processes of manufacturing the semiconductor package using the connection structure illustrated in FIG. 9F as portions of the method of manufacturing the semiconductor package according to an exemplary embodiment in the present disclosure.

Referring to FIG. 10A, the semiconductor chip 110 may be mounted on the connection structure 130, and may be molded using the encapsulant 170.

The plurality of semiconductor chips 110a to 110h may be disposed to be sequentially offset so as to expose the connection electrodes 115. The plurality of semiconductor chips 110a to 110h may be connected to each other through the first wires 165a, and may be connected, respectively, to the first pads 124 disposed in the connection structure 130 through the second wires 165b.

Additionally, the semiconductor chip 110 may be fixed on the connection structure 130 using the encapsulant 170. The encapsulant 170 may be formed by laminating a film form or applying and hardening a liquid phase form. In the present process, a case in which connection is made in a wire bonding manner is exemplified. However, the connection is not limited thereto, and may be made in a flip-chip-bonding manner using a solder in the present mounting process. In this case, the semiconductor chip and the connection structure may be more stably attached to each other by an underfill resin.

Then, referring to FIG. 10B, the carrier substrate 210 may be removed from the connection structure 130, and a plurality of openings 140p may then be formed in the insulating layer 140 for passivation.

As described above, the insulating layer 140 for passivation may be formed of an insulating material that may improve the reliability of the board level and is easily laser-drilled, unlike the material of the insulating layers 131a, 131b, and 131c of the insulating member 131. For example, the insulating layers 131a, 131b, and 131c may include the photosensitive insulating material such as the PID, while the insulating layer 140 may include a non-photosensitive insulating material such as the ABF.

In the present process, the openings 140p opening portions of the second pads 122 may be formed in the insulating layer 140 for passivation by the laser drilling. Residues due to the laser drilling may be easily removed by a Descum or etching process using oxygen plasma, or the like.

Then, referring to FIG. 10C, the electrical connection metals 150 may be formed on the second pads 122 exposed by the plurality of openings 140p.

The electrical connection metals 150 formed in the present process may physically and/or electrically externally connect the semiconductor package 100. Each of the electrical connection metals 150 may be formed of a conductive material and a low melting point metal such as tin (Sn) or alloys including tin (Sn).

The series of processes described above may be performed using a panel structure having a large area, and when a dicing process is performed after the series of processes are completed, a plurality of semiconductor packages 100 may be manufactured by performing the process once.

As set forth above, according to an exemplary embodiment in the present disclosure, a semiconductor package capable of having a small size and a high reliability may be provided.

In a specific exemplary embodiment, an insulating member formed of a PID and vulnerable to external impact may not be exposed, a passivation layer formed of the other material (for example, ABF) may be used to expose pads (that is, second pads or UBM pads) for external connection, and plating layers may be prevented from being formed on side surfaces of pads (that is, first pads or bonding pads) for connection to a semiconductor chip, such that an unnecessary increase in a width of the pads may be prevented and a fine pitch may be implemented.

While exemplary embodiments have been shown and described above, it will be apparent to those skilled in the art that modifications and variations could be made without departing from the scope of the present invention as defined by the appended claims.

What is claimed is:

1. A semiconductor package comprising:
a connection structure including an insulating member having a first surface having a recess portion and a second surface opposing the first surface, a plurality of first pads disposed on a bottom surface of the recess portion, a plurality of second pads embedded in the second surface of the insulating member, and a redistribution layer disposed between the plurality of first pads and the plurality of second pads and connected to the plurality of first and second pads;
a semiconductor chip disposed on the first surface of the insulating member and having a plurality of connection electrodes electrically connected, respectively, to the plurality of first pads; and
a passivation layer disposed on the second surface of the insulating member and having a plurality of openings exposing, respectively, the plurality of second pads.

2. The semiconductor package of claim 1, wherein the redistribution layer includes an upper redistribution layer disposed on the same level as that of the first pad on the insulating member, and
the upper redistribution layer is electrically connected to the first pads or the other region of the redistribution layer.

3. The semiconductor package of claim 1, wherein each of the plurality of first pads includes a metal pad and metal layers disposed on an upper surface of the metal pads, and side surfaces of the metal pad are exposed.

4. The semiconductor package of claim 3, wherein the metal pad includes a copper (Cu) pad, and the metal layers include nickel/gold (Ni/Au) layers.

5. The semiconductor package of claim 3, wherein the plurality of first pads are arranged in a pitch of 65 μm or less.

6. The semiconductor package of claim 1, wherein the plurality of connection electrodes are connected to the plurality of first pads by wires.

7. The semiconductor package of claim 1, wherein the plurality of second pads are substantially coplanar with the second surface of the insulating member.

8. The semiconductor package of claim 1, wherein the redistribution layer includes a plurality of redistribution patterns disposed on different levels of the insulating member and a plurality of redistribution vias connected, respectively, to the plurality of redistribution patterns.

9. The semiconductor package of claim 8, wherein the redistribution via has a greater width in a portion thereof adjacent to the first surface than in a portion thereof adjacent to the second surface.

10. The semiconductor package of claim 8, wherein each of the plurality of redistribution vias has an integrated structure with the redistribution pattern adjacent to the second surface.

11. The semiconductor package of claim 1, wherein the insulating member includes a photosensitive insulating material, and the passivation layer includes a non-photosensitive insulating material.

12. The semiconductor package of claim 1, further comprising a plurality of electrical connection metals disposed on the passivation layer and connected to the plurality of second pads through the plurality of openings, respectively.

13. The semiconductor package of claim 1, wherein the semiconductor chip is a high bandwidth memory (HBM) chip.

14. A semiconductor package comprising:
a connection structure including an insulating member having a first surface having a recess portion and a second surface opposing the first surface, a plurality of bonding pads disposed on a bottom surface of the recess portion, and a redistribution layer disposed on the insulating member and connected to the plurality of bonding pads;
at least one semiconductor chip disposed on the first surface of the insulating member and having a plurality of connection electrodes connected, respectively, to the plurality of bonding pads by wires;
an encapsulant disposed on the first surface of the insulating member and encapsulating the at least one semiconductor chip;
a plurality underbump metallurgy (UBM) pads electrically connected to the redistribution layer and embedded in the second surface of the insulating member; and
a passivation layer disposed on the second surface of the insulating member, having a plurality of openings exposing, respectively, the plurality of UBM pads, and including an insulating material different from that of the insulating member.

15. The semiconductor package of claim 14, wherein the insulating member includes a plurality of insulating layers including a first insulating layer providing the first surface and a second insulating layer adjacent to the first insulating layer, and
the first insulating layer has bonding openings formed in a region corresponding to the recess portion, and the bottom surface of the recess portion is provided by one region of an upper surface of the second insulating layer defined by the bonding openings.

16. The semiconductor package of claim 15, wherein the redistribution layer includes an upper redistribution layer disposed on the other region of the upper surface of the second insulating layer, and
the upper redistribution layer is electrically connected to the bonding pads or the other region of the redistribution layer.

17. The semiconductor package of claim 1, wherein some of the plurality of first pads have a via having an integrated structure with the first pads.

18. The semiconductor package of claim 11, wherein the photosensitive insulating material is a photoimagable dielectric resin.
